(19) United States
(12) Patent Application Publication
(10) Pub. No.: US 2014/0234977 A1
(43) Pub. Date: Aug. 21, 2014

(54) ROLLED-UP, THREE-DIMENSIONAL FIELD-EFFECT TRANSISTORS AND THE USE THEREOF IN ELECTRONICS, SENSORS AND MICROFLUIDICS

(71) Applicant: LEIBNIZ-INSTITUT FUER FESTKOERPER-UND WERKSTOFFFORSCHUNG DRESDEN E.V, Dresden (DE)

(72) Inventors: Daniel GRIMM, Dresden (DE); Oliver G. SCHMIDT, Dresden (DE); Carlos Cesar Bof BUFON, Jaguariuna (BR)

(73) Assignee: LEIBNIZ-INSTITUT FUER FESTKOERPER-UND WERKSTOFFFORSCHUNG DRESDEN E.V, Dresden (DE)

(21) Appl. No.: 14/094,135

(22) Filed: Dec. 2, 2013

(30) Foreign Application Priority Data
Nov. 30, 2012 (DE) 102012221932.3

(51) Int. Cl. G01N 27/414

(52) U.S. Cl. CPC G01N 27/414
USPC 436/39; 257/253; 436/131; 436/93; 436/132; 436/130; 436/120; 436/126

(57) ABSTRACT

Field-effect transistors include at least two thin layers of a semiconductor material and of an electrically conductive gate material that are rolled up together. These two layers are arranged separated from one another by one or multiple barrier layers and this rolled-up multi-layer structure is integratable as field-effect transistors in circuits and/or in microfluid systems as sensors for the detection of fluids.

### CROSS-REFERENCE TO RELATED APPLICATIONS

The present application claims priority under 35 U.S.C. §119(a) of German Patent Application No. 10 2012 221 932.3 filed Nov. 30, 2013.

### BACKGROUND OF THE INVENTION

1. Field of the Invention

The present application claims priority under 35 U.S.C. §119(a) of German Patent Application No. 10 2012 221 932 filed Nov. 30, 2012, the disclosure of which is expressly incorporated by reference herein in its entirety.

The invention relates to the field of electrical engineering/electronics and relates to field-effect transistors, as they can for example be used in electronic circuits or as sensor elements.

2. Discussion of Background Information

Field-effect transistors or FETs are a group of unipolar transistors in which in contrast to the bipolar transistors only one charge type is involved in the current transport—depending on the design with electrons or holes or defect electrons. At low frequencies, they are—in contrast to the bipolar transistors—switched mostly without power and without loss. The most widespread type of field-effect transistor is the MOSFET (metal-oxide semiconductor field-effect transistor).

In contrast to the current-controlled bipolar transistors, field-effect transistors are voltage-controlled circuit elements. The deciding switching-related difference from the bipolar transistor is the virtually powerless actuation of the FET at low frequencies; only a control voltage is required. The control occurs via the gate-source voltage, which serves to regulate the channel cross section or the charge-carrier density, that is, the semiconductor resistance, in order to thus switch or control the strength of an electric current. The FET has three connections: the source (S), the gate (G) and the drain (D).

The control and amplification of the current flow between the drain and source occurs by the targeted increase and decrease of conductive and non-conductive regions of the semiconductor material. The semiconductor material, which is p-doped and n-doped in advance, is thereby either depleted by the applied voltage or the electric field thus produced or enhanced with charge carriers.

Also known is the independent rolling-up of strained thin-layer capacitors when these capacitors are detached from a substrate [EP2023357B1].

Likewise, the production of rolled resistors (F. Cavallo, et al: Applied Physics Letters, Vol. 93, No. 14, p. 143113-143113-3, October 2008) or the production of wound thermoelectric components (DE 10 2008 040472 A1) are known.

According to S. Mendach, et al: Physica E: Low-dimensional Systems and Nanostructures, Vol. 23, No. 3-4, p. 274-279, July 2004, the production of curved two-dimensional electronic systems in InGaAs/GaAs microtubes is known.

Furthermore, the behavior of liquids and gases in the smallest of spaces is studied by means of microfluidics. This behavior can differ significantly from the behavior of macroscopic fluids, as in this order of magnitude effects can dominate that are often ignored in classic fluid mechanics. If for example the frictional forces dominate the inertial forces, which corresponds to a flow at low Reynolds numbers, a laminar flow occurs without considerable turbulences. This impedes the mixing of liquids, which without turbulence only occurs through diffusion. Another difference is the possible dominance of capillary forces over the gravitational force. This manifests itself in a low Bond number and results, contrary to everyday experience, in the possibility of ignoring the gravitational force during the transport of very small amounts of liquid.

The disadvantages of the prior art are that the known field-effect transistors with high flows have a relatively large space requirement on microchips or other components.

### SUMMARY OF THE EMBODIMENTS

The object of the present invention is the disclosure of rolled-up, three-dimensional field-effect transistors that demonstrate a compact design with a low space requirement and are also usable in circuits as an integrative component and/or as sensors in microfluidics.

The object is attained by the invention disclosed in the claims. Advantageous embodiments are the subject matter of the dependent claims.

The field-effect transistors according to the invention are composed of at least two thin layers of a semiconductor material and of an electrically conductive gate material rolled up together, wherein these two layers are arranged separated from one another by one or multiple barrier layers and wherein this rolled-up multi-layer structure is integrated as field-effect transistors in circuits and/or in microfluid systems as sensors for the detection of fluids.

Advantageously, an inorganic semiconductive material of one or multiple elements of the main group III, V, and/or IV is present as semiconductor material; even more advantageously gallium, arsenic, indium, phosphorus, aluminum, silicon and/or germanium or oxides or alloys thereof are present as semiconductor material.

Also advantageously, titanium, chromium, copper, gold, silver, nickel or other metals and alloys thereof or highly doped polycrystalline semiconductors, such as for example silicon or germanium, are present as electrically conductive gate-material.

Also advantageously, oxidic materials for the barrier layers are present that even more advantageously are SiO2, SiOx, Si3N4, Y2O3, Al2O3, HfO2, HfSiON, HfSiO, TiO2, BaSrTiOx, ZrO, La2O3, Ta2O5, oxidized InAlP, Ga2O3, Gd2O3, (GdxGal-x)2O3 or other dielectrics with high dielectric constants.

Also advantageously, there is no material contact between the layers of semiconductor material and gate material.

It is also advantageous if the transistor is produced with an insulated gate and/or as a metal semiconductor field-effect transistor and/or as an HEMT (transistor with high electron mobility) which is produced with or without an insulated gate.

And it is also advantageous if the transistor is a transistor of the depletion type or of the enhancement type, wherein even more advantageously a transistor of the enhancement type has p-dopings or n-dopings that are achieved by doping the semiconductor material with P, B, As, Ga, C, Si, N, B, P, Zn and/or ZnO.

According to the invention, field effect transistors are used in circuits and/or in microfluid systems as sensors for the detection of fluids or as actively or passively cooled field-effect transistors.

Advantageously, the field-effect transistors are integrated in CMOS technology in circuits.

And also advantageously, the field-effect transistors in microfluid systems are actively or passively cooled using water, oil, glycerol or solvent.

### BRIEF DESCRIPTION OF THE DRAWINGS

FIG. 1 illustrates a field-effect transistor according to the embodiments; and

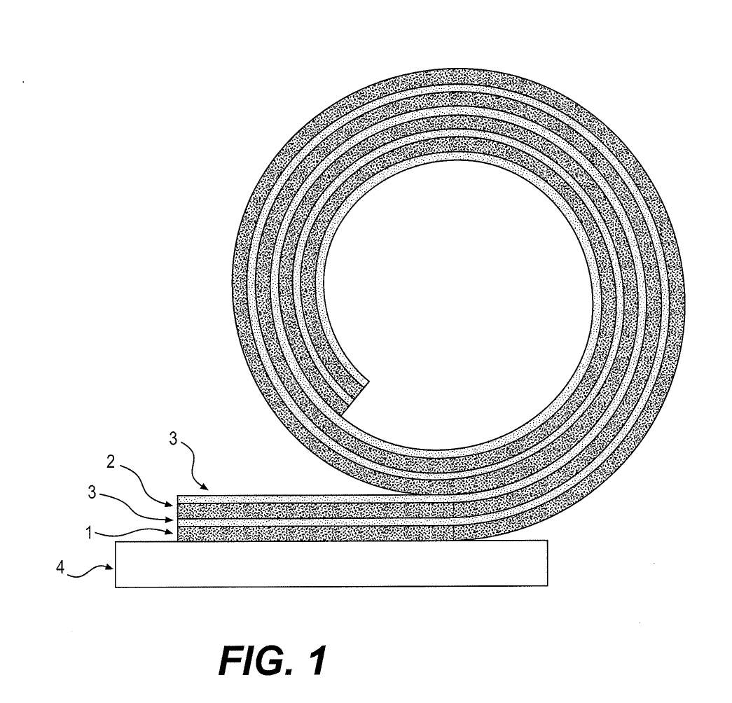

FIG. 2 illustrates a TEM image of a real structure of the field-effect transistor depicted in FIG. 1.

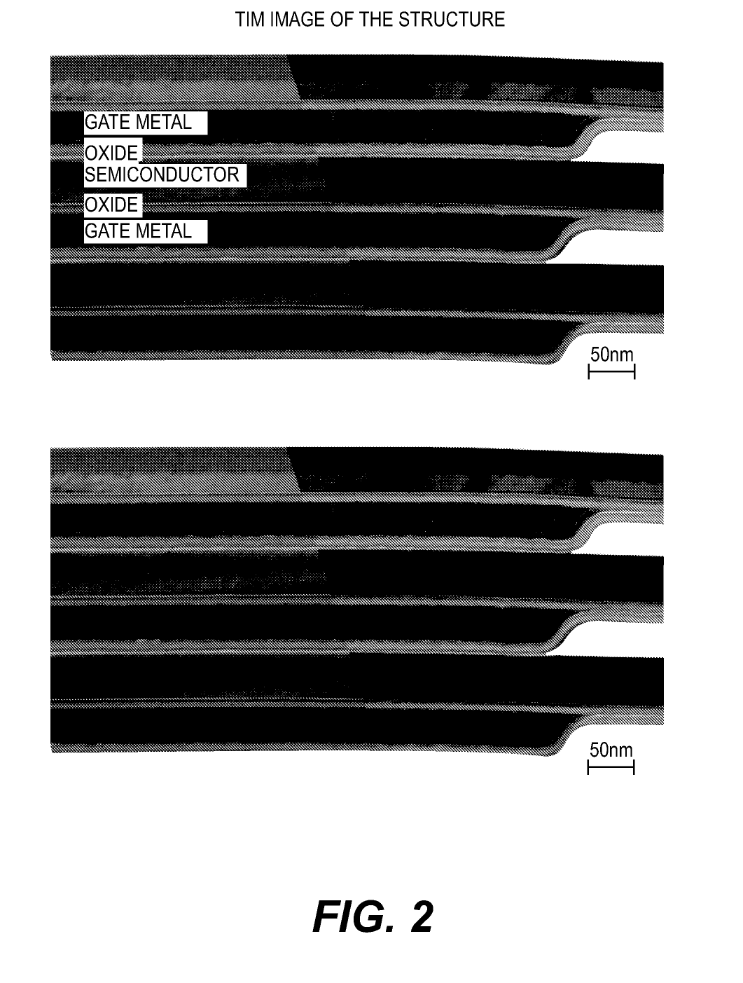

### DETAILED DESCRIPTION OF THE EMBODIMENTS

With the method according to the invention, it becomes possible for the first time to provide rolled-up, three-dimensional field-effect transistors in a compact design with a low space requirement and to use these transistors in circuits as an integrative component and/or in microfluidics as a sensor.

This is achieved by field-effect transistors that are composed of at least two thin layers of a semiconductor material and of an electrically conductive gate material rolled up together.

It is advantageous if the alternating layers of semiconductor material and of electrically conductive gate material are made of at least 2 windings. It is thus possible to produce superstructures of materials that are otherwise not compatible, such as for example multiple layers lying on top of one another made of monocrystalline semiconductors, amorphous dielectrics and polycrystalline electrodes.

As materials for the field-effect transistors according to the invention, inorganic semiconductive materials of one or multiple elements of the main group III, V, and/or IV can be used, which for example are gallium, arsenic, indium, phosphorus, aluminum, silicon and/or germanium or oxides or alloys thereof.

Titanium, chromium, copper, gold, silver, nickel, or other metals or alloys thereof or highly doped, that is, conductive, polycrystalline semiconductors, such as silicon or germanium, can be used as materials for the electrically conductive gate material.

As field-effect transistors according to the invention, transistors can be used with an insulated gate and/or as metal semiconductor field-effect transistors and/or as an HEMT (transistor with high electron mobility) that functions with or without an insulated gate. In the case of the transistor with an insulated gate, the two layers of semiconductor material and electrically conductive gate material are, according to the invention, arranged separated from one another by at least one barrier layer of oxidic material. It is thus prevented that a material contact between the layers of semiconductor material and the layers of gate material is achieved. In the case of the metal semiconductor field-effect transistor, the depletion region in the semiconductor ensures the electric insulation between both materials.

Likewise, the field-effect transistors according to the invention can be a transistor of the depletion type or of the enhancement type, wherein in the case that the transistor is a transistor of the enhancement type, p-dopings or n-dopings are present that are achieved by doping the semiconductor material with P, B, As, Ga, C, Si, N, B, P, Zn and/or ZnO.

The rolled-up, three-dimensional field-effect transistors are subsequently integrated in circuits and/or in microfluid systems as sensors for the detection of fluids.

The rolled-up multi-layer structure is produced as follows.

A sacrificial layer, for example of silicon, germanium or of AlGaAs compounds, is applied to a substrate, for example of crystalline or polycrystalline silicon, germanium, GaAs or InP. Alternatively, SOI (silicon on insulator) or SGOI (silicon-germanium on insulator) substrates can be used, wherein the embedded oxide can be used as a sacrificial layer.

The layer of a semiconductor material is subsequently deposited, for example by means of molecular beam epitaxy (MBE) or by means of chemical vapor deposition or by means of metalorganic chemical vapor deposition or by means of plasma-assisted chemical vapor deposition or by means of vaporization techniques or by means of sputtering techniques.

Inorganic semiconductive materials of one or multiple elements of the main group III, V and/or IV, advantageously gallium, arsenic, indium, phosphorus, aluminum, silicon and/or germanium or oxides or alloys thereof can be deposited as semiconductor materials.

The layer of semiconductor material can be deposited with or without strain. The strain can be achieved by varying the lattice constants or by strained, subsequently deposited oxide and/or electrode layers.

The necessary electrodes for the electrical connection of the field-effect transistor according to the invention are for example composed of metal or of a doped polysilicon and can likewise be applied with or without strain.

An insulating barrier layer of SiO₂, SiOₓ, Si₃N₄, Y₂O₃, Al₂O₃, HfO₂, HfSiON, HfSiO, TiO₂, BaSrTiOx, ZrO, La₂O₃, Ta₂O₅, oxidized InAlP, Ga₂O₃, Gd₂O₃, (GdₓGa₁₋ₓ)₂O₃ or a different dielectric with a high dielectric constant is deposited thereon. This layer can thereby be applied with or without a strain.

In turn, a layer of a metallic gate material is deposited thereon. Titanium, chromium, copper, gold, silver, nickel, or other metals and alloys thereof, or highly doped polycrystalline semiconductors such as silicon or germanium can be used as gate material.

The layer of the electrically conductive gate material can thereby be applied with or without a strain.

The sacrificial layer is subsequently removed, for example by means of selective etching.

For the production of complementary transistors, for example for use in CMOS technology, the necessary p-dopings or n-dopings with elements or compounds such as P, B, As, Ga, C, Si, N, B, P, Zn oder ZnO are achieved by high-temperature diffusion processes with the aid of spin-on glass or by doping in a gaseous environment or by ion implantation. It is thus possible to produce adjacent FETs in the rolled-up structure such that they have any desired doping and therefore any desired p-channel or n-channel. The p-FETs and n-FETs rolled up using the known roll-up technology then act in a complementary manner and can for example be integrated into a CMOS circuit. The crystal structure is reproduced after the implantation using a high-temperature annealing step. Normally, the surface is protected by a selectively removable oxide, such as SiO₂ or Al₂O₃, during the implantation process.

The rolled-up microtubes produced as a whole have a function as a field-effect transistor, but also simultaneously a function as a sensor for fluids. Thus, the rolled-up microtubes can be used as field-effect transistors, in particular with the aid of CMOS technology, in integrated circuits. Based on the basic principle of CMOS technology in digital technology, p-channel and n-channel field-effect transistors are combined in the circuits.

The rolled-up microtubes can furthermore be integrated at the desired position in microfluid systems as sensors for fluids. When fluids are conducted through the microtubes, these fluids can be detected. If, for example, a glass capillary with approx. a 5 μm inner diameter and a drop of a solvent of approx. 5 pl is brought into the proximity of the opening of the microtube, then the capillary forces draw the liquid into the microcavity and are electrically detected by the field-effect transistor according to the invention.

As fluids, both liquids and also gases can be conducted through the microtube. The detection of polar liquids or gases, such as water, isopropanol C₃H₈O, tetrahydrofuran C₄H₈O, ethanol C₂H₆O, acetone C₃H₆O, dimethyl sulfoxide C₂H₆OS or dichloromethane CH₂Cl₂ is particularly advantageous.

In both cases of application, that is, in circuits and/or microfluid systems, the microtubes can be produced at the application site, that is, be rolled up there, or produced locally at a different site and then integrated into the final position in the circuits and/or microfluid systems. The final position can thereby be predefined by the lithographic patterning.

The particular advantage of the field-effect transistors according to the invention is not only the application thereof in circuits and/or in microfluidics, but also the compact three-dimensional design thereof with a low space requirement. With the now three-dimensional design of the field-effect transistors, these transistors can be arranged in electronic components and circuits in a different manner. The possible field of application is thereby increased.

Another particular advantage is that the field-effect transistors according to the invention always have a so-called double-gate transistor arrangement after the rolling-up of the layers. Each layer of the semiconductor material is bordered on both sides by a layer of gate-insulation material. Both gate materials thus influence the semiconductor layer.

With the solution according to the invention, the field-effect transistors can for example be installed in a device that is flowed through by a cooling liquid in a microfluid system. The hollow interior of the field-effect transistor according to the invention is filled with the cooling liquid, or the cooling liquid flows through the interior. Water, oils, glycerol or solvent can be used as cooling liquids, the temperature of which is lower than the ambient temperature of the microfluid system. The cooling of the liquid can thereby occur via an external cooling circuit or by evaporation. The switching properties and the power consumption can thus be positively influenced.

A possible embodiment of the field-effect transistor according to the invention shows for example as a planar component the dimensions of 10 μm length and 400 μm width with one layer each of a semiconductor material and a gate material with a barrier layer of an oxidic material arranged therebetween. After the rolling-up, the microtube has a tubular radius of ˜5 lam with 12 windings and a length of 1.5 mm with multiple parallel field-effect transistors. The finished rolled-up field-effect transistors show an on-current of 10-100 μA at an applied positive gate voltage of 1 V. In the switched-off state at an applied negative gate voltage of −2 V, the field-effect transistor does not show measurable currents (under 1 nA). The amount of the leakage current (from the gate to the source) is less than 1 nA.

After the rolling-up of the layers, a tube is present with the dimensions 10×1500 μm² and with multiple field-effect transistors.

The invention is explained below in greater detail with the aid of several exemplary embodiments.

### Example 1

For the production of a flexible three-dimensional field-effect transistor with an insulated gate of the depletion type category for use as a microfluidic channel for the detection of polar fluids, a 40 nm-thick sacrificial layer of undoped AlAs is applied to an undoped 2-inch GaAs wafer on the entire wafer by means of MBE. A 20 nm-thick layer of undoped In_{0.2}Ga_{0.8}As is subsequently applied by means of MBE such that the monocrystalline layer has a strain. A 30 nm-thick layer of GaAs with an n-doping of ˜3.5×10¹⁸ cm⁻³ is applied thereto as a semiconductor layer by means of MBE such that the monocrystalline layer has a strain. The necessary strain is set by the approximately 1.4-percent difference of the lattice constants.

The insulation of the individual components of the field-effect transistor occurs through wet-chemical etching in a mixture of sulfuric acid, hydrogen peroxide and water with an etching depth of 50 nm.

The low-impedance contacts with the semiconductor layer are produced by the deposition of 8.8 nm of Ge, 17.8 nm of Au and 10 nm of Ni using electron beam evaporation at 10⁴ Pa.

A surface passivation is then performed using HF, and a subsequent atomic layer deposition of the oxidic barrier layer of 11 nm of Al₂O₃ is performed at 200° C.

The gate contacts are produced by a deposition of 16 nm of Ti and 22 nm of Cr using electron beam evaporation at max. 10⁵ Pa.

Finally, an additional dielectric layer of 11 nm Al₂O₃ is deposited at 200° C. by means of atomic layer deposition.

The wet-chemical etching of the bond contacts occurs within 10 sec. using 2:30 HF:H₂O, and 5 nm of Cr and 100 nm of Au are deposited as bond pads using electron beam evaporation at max. 10⁴ Pa.

There then occurs the wet-chemical etching of a deep cut with access to the sacrificial layer within 18 sec. using 2:30 HF:H₂O and subsequently within 10 sec. using 1:2:1 K₂Cr₂O₇:HBr:C₂H₄O₂.

The selective etching of the sacrificial layer with the result of a release and rolling-up of the strained layer is performed in 1:1 HCl:H₂O within 30 min. The layer rolling itself up is thus composed of the semiconductor layer of 20 nm of In_{0.2}Ga_{0.8}As and 30 nm of GaAs, the conductive source-drain contacts of 36.6 nm of NiGeAu, followed by 11 nm of Al₂O₃ as an oxidic barrier layer, thereafter the gate electrodes of 38 nm of TiCr, and finally 11 nm of Al₂O₃ as an oxidic barrier layer for the rolled-up component.

To improve the contact resistance, the rolled-up field-effect transistor is subsequently heated for 1.5 min. at 430° C. in a forming gas environment.

All patternings occur by means of optical lithography comprising the following individual steps:
Temperature treatment on hot plate, 120° C. for 2 minutes,
Spin-on application of the photoresist at 4500 rpm for 30 sec.,
Curing on the hot plate for 5 minutes at 90° C.,
Exposure
In the case of negative resists: temperature treatment on hot plate, 120° C. for 2 minutes and flood exposure
Development of the exposed resist,
Etching or deposition of the conductive layers,
Removal of the resist structures and possibly deposited layers,
Cleaning of the substrate.

These rolled-up field-effect transistors are then integrated into a microfluid system.

As a sensor element, the field-effect transistor according to the invention is typically operated in the on-state, that is, at a gate voltage of 1 V and a source-drain voltage of 1 V. Once the polar fluid of water has been introduced into the microtube, an increase in the current of 100% is detected. Once the fluid feed has been stopped and the fluid has been removed, an exponential drop in the current to the level prior to the injection of the fluid can be observed. After less than 1 minute, the previous current level is reached and the microtube can once again be used as a sensor. The detection method also works in the case of a variation of the gate-drain and/or source-drain voltage.

### Example 2

For the production of a flexible three-dimensional HEMT with an insulated gate of the depletion type category, a 40 nm-thick sacrificial layer of undoped AlAs is applied to an undoped 2-inch GaAs wafer. All semiconductor layers are applied to the entire wafer by means of MBE. The semiconductor layer made of the following multi-layers is subsequently applied:

| Layer thickness | Material | Doping | Functionality |
|---|---|---|---|
| 2 nm | In_{0.2}Ga_{0.8}As | — | Strained layer |
| 12 nm | In_{0.2}Ga_{0.2}Al_{0.6}As | — | Strained layer |
| 3 nm | Al_{0.33}Ga_{0.67}As | — | Distancing layer |
| 11 nm | Al_{0.33}Ga_{0.67}As | 3.5 × 10¹⁸ (Si) | Electron dopant |
| 3 nm | Al_{0.33}Ga_{0.67}As | — | Distancing layer |
| 12 nm | GaAs | — | Conducting channel |
| 3 nm | Al_{0.33}Ga_{0.67}As | — | Distancing layer |
| 14 nm | Al_{0.33}Ga_{0.67}As | 2.5 × 10¹⁸ (Si) | Electron dopant |
| 3 nm | Al_{0.33}Ga_{0.67}As | — | Distancing layer |
| 2 nm | GaAs | — | Protective layer |

All subsequent process steps are identical to Example 1. The resulting tube has a larger radius of 9 μm due to the thicker layer stack. The electronic properties are comparable to Example 1, but the three-dimensional HEMTs show a larger on-current of 1 mA.

### Example 3

For the production of flexible three-dimensional complimentary field-effect transistors with an insulated gate of the enhancement type category, a 40 nm-thick sacrificial layer of undoped AlAs is applied to an undoped 2-inch GaAs wafer on the entire wafer by means of MBE. A 20 nm-thick layer of undoped In_{0.2}Ga_{0.8}As is subsequently applied by means of MBE such that the monocrystalline layer has a strain. A 30 nm-thick layer of undoped GaAs is applied thereto by means of MBE such that the monocrystalline layer has a strain. The necessary strain is set by the approximately 1.4-percent difference of the lattice constants.

The insulation of the individual components of the field-effect transistor occurs through wet-chemical etching in a mixture of sulfuric acid, hydrogen peroxide and water with an etching depth of 50 nm.

A 30 nm-thick Al₂O₃ protective layer is applied using atomic layer deposition at 200° C. The necessary doping at the source and drain regions is performed using an ion implantation of Si for n-MOSFETs and Zn for p-MOSFETs. Using lithography, the necessary selectivity is achieved; the surface doping is approximately 10¹⁵. The activation of the implant and the annealing of the lattice are achieved by a fast baking for 15 sec. in a forming gas atmosphere. The silicon doping is thereby completed first at a baking temperature of 800° C., then the Zn doping at 750° C. The protective layer is subsequently removed within 45 sec. by means of 2:30 HF:H₂O.

The low-impedance contacts with the semiconductor layer are produced by the deposition of 8.8 nm of Ge, 17.8 nm of Au and 10 nm of Ni for the n-MOSFETs and 10 nm of Pt, 20 nm of Ti and 10 nm of Pt for the p-MOSFETs using electron beam evaporation at 10⁴ Pa. A surface passivation is then performed using HF, and a subsequent atomic layer deposition of 11 nm of Al₂O₃ is performed at 200° C.

The gate contacts are produced by a deposition of 16 nm of Ti and 22 nm of Cr using electron beam evaporation at max. 10⁵ Pa. By suitably connecting the parallel FETs, any number of logical circuits can be achieved, in particular CMOS circuits. By connecting two opposing layers that are to be rolled up, it is also possible to achieve additional circuits.

Finally, an additional dielectric layer of 11 nm of Al₂O₃ is deposited at 200° C. by means of atomic layer deposition.

The wet-chemical etching of the bond contacts occurs within 10 sec. using 2:30 HF:H₂O, and 5 nm of Cr and 100 nm of Au are deposited as bond pads using electron beam evaporation at max. 10⁴ Pa.

There then occurs the wet-chemical etching of a deep cut with access to the sacrificial layer within 18 sec. using 2:30 HF:H₂O and subsequently within 10 sec. using 1:2:1 K₂Cr₂O₇:HBr:C₂H₄O₂.

The selective etching of the sacrificial layer with the result of the release and rolling-up of the strained layer and the circuits processed thereon is performed within 30 min. in 1:1 HCl:H₂O.

To improve the contact resistance, the rolled-up field-effect transistor is subsequently heated for 1.5 min. at 430° C. in a forming gas environment.

### LIST OF REFERENCE NUMERALS

1 thin layer of semiconductor material
2 thin layer of electrically conductive gate material
3 barrier layer
4 substrate

1. Field-effect transistors composed of at least two thin layers of a semiconductor material (1) and of an electrically conductive gate material (2) rolled up together, wherein these two layers are arranged separated from one another by one or multiple barrier layers (3) and wherein this rolled-up multi-layer structure is integrated as field-effect transistors in circuits and/or in microfluid systems as sensors for the detection of fluids.

2. Field-effect transistor according to claim 1, in which an inorganic semiconductive material of one or multiple elements of the main group III, V and/or IV is present as semiconductor material (1).

3. Field-effect transistor according to claim 2, in which gallium, arsenic, indium, phosphorus, aluminum, silicon and/or germanium or oxides or alloys thereof are present as semiconductor material (1).

4. Field-effect transistor according to claim 1, in which titanium, chromium, copper, gold, silver, nickel or other metals and alloys thereof or highly doped polycrystalline semiconductors, such as for example silicon or germanium, are present as electrically conductive gate-material (2).

5. Field-effect transistor according to claim 1, in which oxidic materials for the barrier layers (3) are present.

6. Field-effect transistor according to claim 5, in which SiO₂, SiOx, Si₃N₄, Y₂O₃, Al₂O₃, HfO₂, HfSiON, HfSiO, TiO₂, BaSrTiOx, ZrO, La₂O₃, Ta₂O₅, oxidized InAlP, Ga₂O₃, Gd₂O₃, (GdₓGa₁₋ₓ)₂O₃ or other dielectrics with high dielectric constants are present as oxidic materials for the barrier layers (3).

7. Field-effect transistor according to claim 1 in which there is no material contact between the layers of semiconductor material (1) and gate material (2).

8. Field-effect transistor according to claim 1 in which the transistor is produced with an insulated gate and/or as a metal semiconductor field-effect transistor and/or as an HEMT (transistor with high electron mobility) which is produced with or without an insulated gate.

9. Field-effect transistor according to claim 1 in which the transistor is a transistor of the depletion type or of the enhancement type.

10. Field-effect transistor according to claim 9 in which a transistor of the enhancement type has p-dopings or n-dopings that are achieved by doping the semiconductor material with P, B, As, Ga, C, Si, N, B, P, Zn and/or ZnO.

11. Use of field-effect transistors according to claim 1 in circuits and/or in microfluid systems as sensors for the detection of fluids or as actively or passively cooled field-effect transistors.

12. Use according to claim 11 in which the field-effect transistors are integrated in CMOS technology in circuits.

13. Use according to claim 11 in which the field-effect transistors in microfluid systems are actively or passively cooled using water, oil, glycerol or solvent.
